(19) United States
(12) Patent Application Publication
(10) Pub. No.: US 2013/0069499 A1
(43) Pub. Date: Mar. 21, 2013

(54) Modular case and componentry for handheld electronic devices

(71) Applicant: Paul Modrell, Danville, CA (US)

(72) Inventor: Paul Modrell, Danville, CA (US)

(21) Appl. No.: 13/373,431

(22) Filed: Nov. 14, 2011

Related U.S. Application Data
(60) Provisional application No. 61/451,306, filed on Mar. 10, 2011.

(51) Int. Cl. H05K 5/02

(52) U.S. Cl. CPC H05K 5/02
USPC 312/223.1

(57) ABSTRACT

A case for handheld electronic device, having a housing configured to couple to and cover at least a portion of one or more surfaces of the handheld electronic device. The case includes a detachable cover having a fixed end opposite a free end, the fixed end forming a hinge with the housing and configured to be detachably released from the housing at the hinge. The housing has a recessed cargo area sized to retain articles within the case. The cover rotates at the hinge from a stowed configuration to an open configuration with respect to the housing. In the stowed configuration, the free end of the cover is positioned adjacent the housing to enclose the cargo area. In the open configuration, the free end is rotated away from the housing to expose the cargo area.

### CROSS-REFERENCE TO RELATED APPLICATIONS

This application claims priority from U.S. provisional application Ser. No. 61/451,306, filed on Mar. 10, 2011, herein incorporated by reference in its entirety.

### BACKGROUND OF THE INVENTION

1. Field of the Invention

The present invention relates generally to handheld electronic device utility cases that provide cargo space for tools and personal effects and provide a platform for electronic devices and circuitry. More particularly, the invention is directed to utility cases that provide cargo space for tools and personal effects and provide a platform for electronic devices and circuitry.

2. Description of the Related Art

Various cases are available for protecting handheld electronic devices. Current cell phone and smart phone skins and cases generally only provide a protective or aesthetic outer casing. Some currently available cases add additional features beyond protection of the device, e.g. light, stand, etc. However, because mobile devices such as cellular phones change size and shape frequently, adding significant features to the case that are costly with respect to the device itself are typically not desirable by consumers, as the add-on component would be rendered obsolete once the user changes phones/devices.

Accordingly, an object of the present invention is to provide a modular mobile device case that comprises interchangeable components to increase the functionality of the device, while providing protection and the ability to utilize the modular component upon switching devices. At least some of these objectives will be met in the following description.

### BRIEF SUMMARY OF THE INVENTION

An aspect of the present invention is a multi-purpose handheld device casing that integrates many other functions that can work independently from or in tandem with the device, e.g. cell phone, smart phone, personal tablet computers or similar handheld mobile devices.

In one embodiment, case comprises a housing comprising a device side that is adapted to securely couple to and/or encase one or more sides of a particular handheld electronic device. The device side of the case comprises an inner surface that is individually sized to receive any make and model of device, while still allowing access to the device user inputs and interfaces, e.g. touch screen, volume controls, power switch, power/communication inputs, etc.

The opposing outer side of the case preferably comprises a cargo space that is enclosed by a hinged, sliding or snapping interchangeable cover. The cargo space and/or interchangeable cover may be configured to receive items that include, but are not limited to various tools, keys, lanyards, kickstands, writing instruments, personal identification holders, personal safety items, billfolds, cosmetics, mirrors, lenses, sensing or medical instruments, musical instruments, measuring devices and writing instruments. For example, one or more cargo areas of the case and/or cover may comprise integrated circuitry, electronics, switches, sensors, emitters, transmitters and mechanical devices that operate built in instruments that include, but are not limited to flashlights, area lights, laser pointers, communications devices, infrared devices, electromagnetic devices, radio devices, computing devices, computer memory devices, environmental monitoring devices and Bluetooth-enabled devices that work independently from or in tandem with the handheld electronic device being covered or encased.

In one embodiment, a case for a handheld electronic device includes a mirror and cosmetics in the cargo space or cover. The case may include electronics and/or an illumination source to provide a built-in mirror light. Alternatively, the case may comprise an aperture for allowing illumination from a light source on the handheld device (e.g. flash), along with diffusers for balancing the light.

In another embodiment, the case of the present invention may include one or more batteries in the cargo space and/or cover to provide power for any electronics, sensors, computing devices and communication devices present on the case or cover.

In one embodiment, the cargo space may be molded continuously with the casing or attached/covered to the casing by way of a hinged, sliding or snapping cover. Either or both the casing and cargo space may comprise or be integrated with in a continues mold the circuitry, electronics, switches, mechanical devices, power sources, sensors, emitters, transmitters or computing devices. In one embodiment, the integrated component may monitor and track human vital signs and transmit the data to the handheld electronic device, or other device such as a computer.

The inner side of the casings are made to take the shape of handheld electronic devices and securely envelop and hold the casing to the device. The cargo space is molded with or attaches to the outer side of the casing to provide space for and attachments to various tools and other items. The circuitry, electronics, switches, mechanical devices, power sources, sensors, emitters, transmitters, communication devices or computing devices are integrated into the casing and/or the cargo space in a continuous mold or are fitted to the casing and/or cargo space and held in place with screws, threaded attachment, snaps, clasps, hasps and/or adhesives.

In another embodiment, the casing and cargo space components (e.g. hinged cover, or sliding drawers) are preferably configured to fit specific handheld electronic device makes and models and incorporate tools, electronic devices, etc. that compliment them. The casings and cargo space and other detachable components, such as flashlight lenses and battery covers, may be manufactured by the processes of thermoplastic/thermosetting plastic and/or metal injection molding. Individual casing and cargo components/cover may be snapped, screwed, clasped, hasped or bonded together to form a basic unit. Optional tools, electronics and other components may be manufactured by injection molding processes, machining or comprise a compatible accessory from a third party vendor. The casing's components can be resized and the electronic components may be charged by an independent battery source, or be plugged into the handheld electronic device battery.

In another embodiment, the cargo space and electronics may be incorporated into a single mold or separate detachable components. The casing is preferably made to custom fit onto various makes and models of handheld electronic devices. However, the cargo space/cover may be specific to the various make and model of particular handheld electronic device, or be standardized to fit onto any of the multipurpose utility casings.

In a preferred embodiment, the case would be fit over the back of the mobile device and would clasp or wrap firmly around the front edge of the device, leaving the screen, keypad, buttons and jacks of the device accessible. Tools, electronics, personal effects, etc., would be available by opening or unfolding them, detaching them or opening and retrieving them from the cargo space. Personal effects, tools etc., can be stored in the cargo space by opening and re-securing the door/drawer/snap-on cover of the cargo space. Electronic and electrical devices such as flashlights, garage door openers or Bluetooth technology will be turned on and off with switches built into the multipurpose handheld electronic device utility case.

In embodiments where the case includes electronic components, the case may be powered by the handheld electronic device, a disposable battery coupled to the case, or by charging a rechargeable battery with an external power source.

In some embodiments, the cargo space or cover may comprise global positioning system devices, medical monitoring devices or other data logging devices, or be custom fit with tools, instruments and computing devices that expand the functionality of otherwise standardized equipment.

Further aspects of the invention will be brought out in the following portions of the specification, wherein the detailed description is for the purpose of fully disclosing preferred embodiments of the invention without placing limitations thereon.

### BRIEF DESCRIPTION OF THE DRAWINGS

FIG. 1 is a perspective view of a first embodiment of an assembled handheld device case in accordance with the present invention.

FIG. 2 is an exploded perspective view of the case of FIG. 1.

FIG. 3 is a rear perspective view of the case of FIG. 1.

FIG. 4 is a cross-sectional view of the case of FIG. 1.

FIG. 5 shows a perspective view of a second embodiment of an assembled handheld device case in accordance with the present invention, with slideable cargo drawers in a retracted or stowed configuration.

FIG. 6 shows a perspective view of the handheld device case of FIG. 5, with slideable cargo drawers in an expanded configuration in accordance with the present invention.

FIG. 7 is a front perspective view of a third and preferred embodiment of an assembled handheld device case comprising a hinged cover in accordance with the present invention.

FIG. 8 is a front perspective view of a modified version of the case of FIG. 7 with the hinged cover in an open configuration in accordance with the present invention.

FIG. 9 is a rear close-up perspective view of the case of FIG. 7.

FIG. 10 is an exploded perspective view of the hinge and cover of the case of FIG. 7.

FIG. 11 is a perspective view of the cover of the case of FIG. 7 with hinge insert installed.

FIG. 12 is a plan view of a set of different interchangeable components configured to couple with the standardized cargo interface of the case of FIG. 7 in accordance with the present invention.

### DETAILED DESCRIPTION OF THE INVENTION

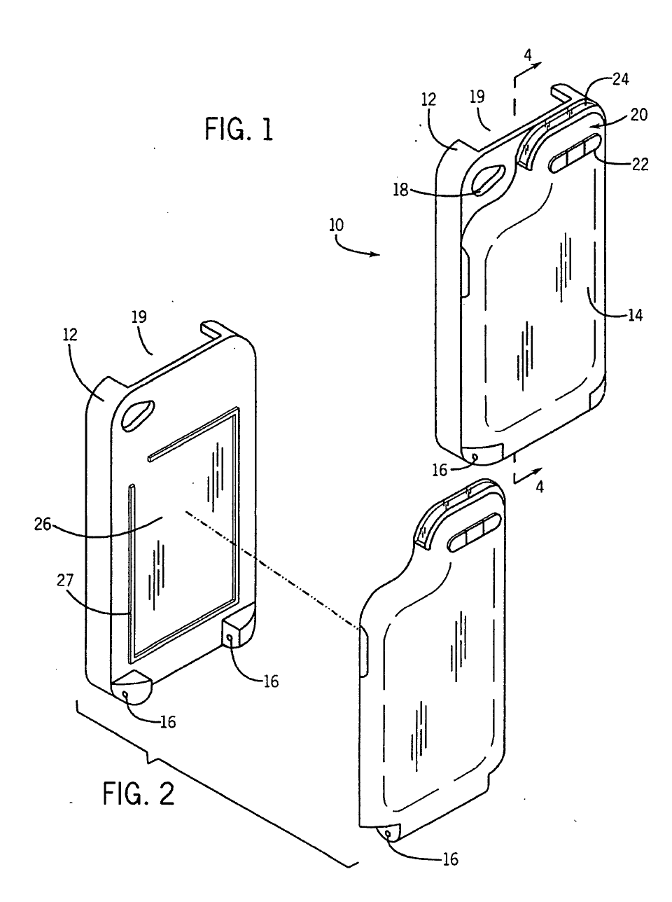

The present invention, detailed in FIGS. 1 to 12 below, is directed to various embodiments of a case configured to couple to a mobile electronics device, all comprising components adapted enhance or add functionality to the device.

FIGS. 1-4 illustrate a first embodiment a utility case 10 configured to interface with an electronic device (not shown) in accordance with the present invention. The case 10 is shown sized specifically to attach to and cover one or more surfaces of a cellular phone, and more specifically an iPhone 4. It is appreciated that the case 10 may be sized to specifically accommodate a number of different cellular phones, or other handheld mobile devices such as PDA's, tablets, media players, or the like.

Referring to FIGS. 1 and 2, the case 10 generally includes two primary components: a housing 12 sized to attach and cover a handheld device, and a pivotable cover 14 configured to interface with the front or cargo surface of the housing 12. The housing 12 includes an opening 18 sized to provide access to functional elements of the device (e.g. power switch, headphone jack, etc.). The housing 12 also comprises a camera aperture 18 configured to allow line of sight for the camera and flash (not shown) of the device.

Case 10 is shown with a built in flashlight 20 housed within the cover 14. The flashlight 20 generally comprises a switch 22 and lens 24 configured to allow the illuminated light from the flashlight 20 to propagate outward from the case 10. It is appreciated that flashlight 20 may also comprise a sensor, emitter transmitter, or the like device, which is configured to receive and/or transmit data being sensed.

As shown in the exploded view in FIG. 2, the cover 14 and housing 12 have matching hinge apertures 16 that allow placement of a hinge pin (not shown) to rotatably attach the cover 14 to housing 12. With the cover 14 in a closed configuration, the cover 14 and front side of housing 12 define a cargo area 26 for holding additional items of interest (e.g. credit card, bills, etc.). The housing 12 may also comprise walls 27 further defining the cargo area. It is appreciated that the cover 14 may be interchangeably attached to or released from the housing 12 to allow for different covers (not shown) having different components or features. For example, covers having the same profile may interface with a standardized hinge area 16 on the case 12 by pulling and/or inserting the hinge pin.

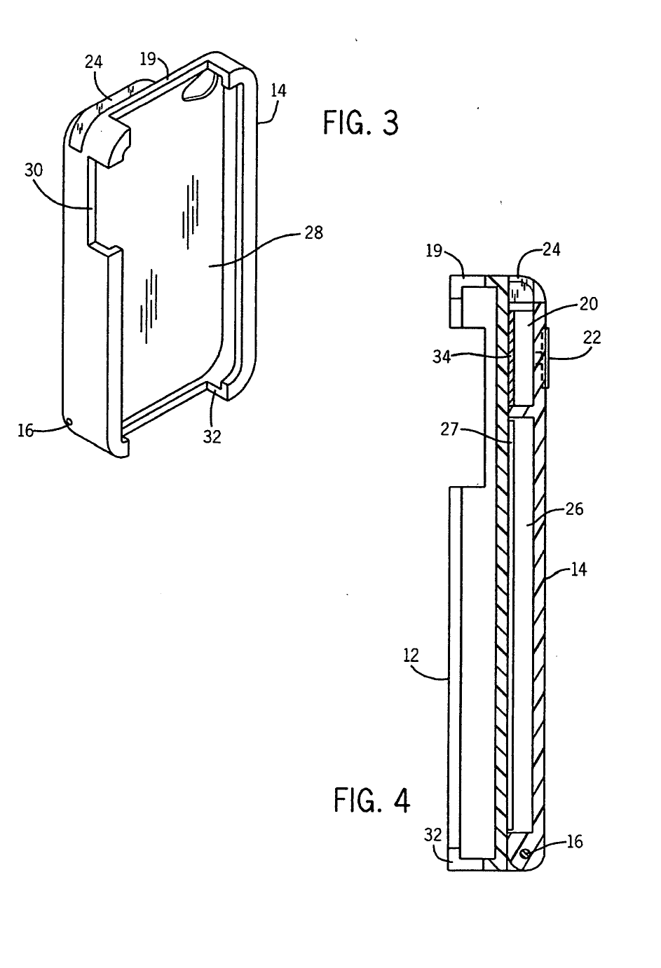

FIG. 3 shows a rear perspective view of the case 10, having a space 28 to allow for housing and securing to the mobile device. The case housing 12 comprises side 30 and bottom 30 openings to provide additional access to device features.

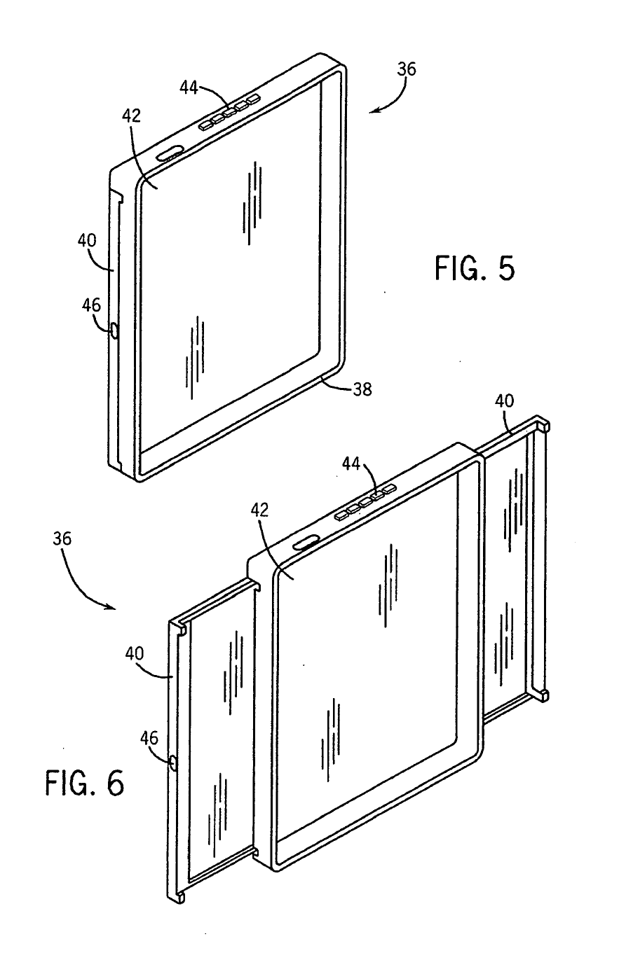

FIG. 4 illustrates a cross-sectional view of the case 10 with cover 14 in a closed or stowed configuration, showing cargo area 26 disposed between walls 27 of housing 12 and inner wall of cover 14. The components of flashlight 20 are also shown in further detail, including circuit board 34, switch 22 and lens 24.

Referring now to FIG. 5, a perspective view of a second embodiment of an assembled handheld device case 36 is shown having lateral slideable cargo drawers 40 in a retracted or stowed configuration. The case comprises a housing 38 having open space 42 for housing or attaching to a handheld device. Housing 38 further comprises push buttons 44 for controlling any electronic component (now shown) integrated with case 10.

FIG. 6 shows a perspective view of the handheld device case 10 of FIG. 5, with the slideable cargo drawers 40 in an expanded configuration. Slideable cargo drawers 40 provide cargo space to hold additional personal effects (e.g. credit cards, bills, etc.), and may include clasps 46 or latch to hold the drawers 40 in a stowed configuration with the housing 38.

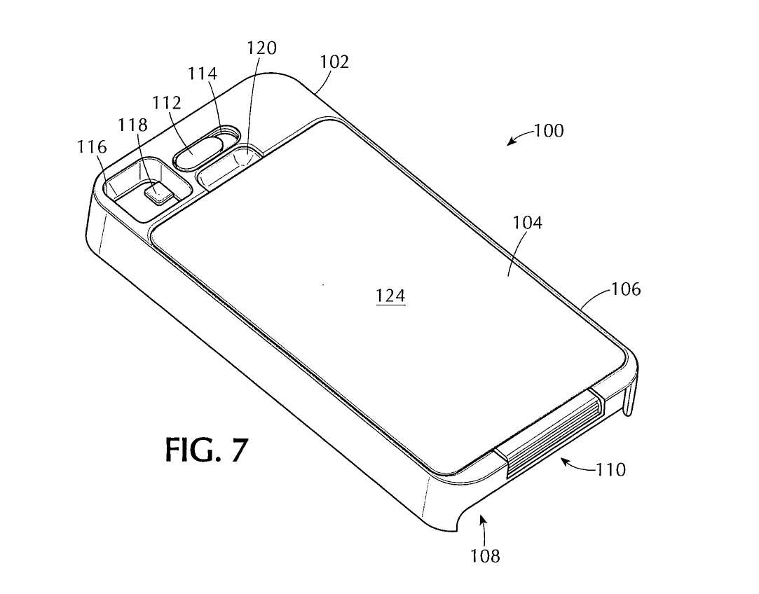

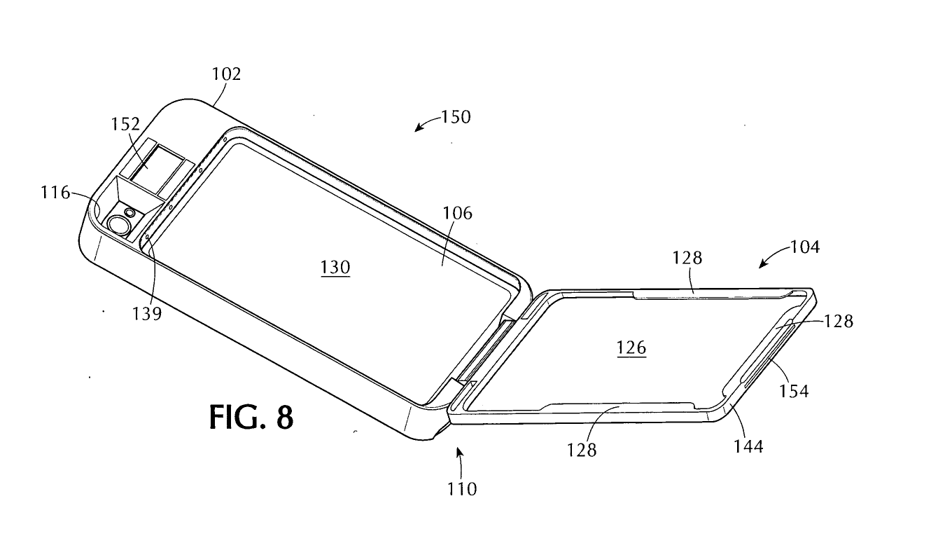

FIGS. 7 through 12 illustrate preferred embodiments of a mobile device case having an interchangeable modular cover in accordance with the present invention. It is appreciated that some of the features disclosed in the various embodiments shown in FIGS. 7 through 12 may be used interchangeably with embodiments shown in FIGS. 1 through 6, and vice versa.

FIG. 7 shows a front perspective view of an assembled handheld device case 100 having an interchangeable hinged cover 104 in a stowed configuration. Case 100 includes a case housing 102 with a recessed cargo space 106 for retaining cover 104 and one or more articles. Cargo space 106 is preferably a standardized space in which the cover 104 is disposed when in a stowed configuration as shown in FIG. 7. The cover 104 is attached to the case housing 102 via hinge assembly 110. A depression 120 in the outer surface of housing 102 (opposite end from hinge 110) allows for insertion of the user's finger to apply leverage to the cover 104 for rotation of the cover to the open configurations shown in FIG. 8. As shown in the stowed configuration shown in FIG. 7, the cover 104 is preferably sized envelope the entire cavity of cargo area 106, with the generally planar outer surface 124 of the cover 104 disposed flush to the housing 102.

Although cases 10, 100 and 150 shown in FIGS. 1-4 and 7-12 show a cover 14, 104 having a hinge 16, 100 at the bottom or lower edge of the case housing 12, 102, (with a horizontal hinge axis and cover 14, 104 opening in a downward rotation), it is appreciated that the hinge may also be positioned at other locations within the case. For example the hinge 16, 100 may be located at a side edge of the case housing 12, 102, with a vertical hinge axis and cover 14, 104 opening in a left or right lateral rotation (not shown).

Case housing 102 is configured to attach to and at least cover a number of surfaces of a mobile handheld electronic device, while allowing access to necessary components of the device. For example, the bottom side of case 102 comprises an opening 108 configured to allow access to various components of the device.

Furthermore, case housing 102 includes a camera window 116 configured to allow for line of sight of the mobile device camera and flash (shown in FIG. 8). The housing 102 is also configured to support a retractable diffuser 118 within window 116. Diffuser 118 is configured to slideably extend into the window 116 and corresponding field of view of the device's flash (e.g. LED flash of iPhone 4), as shown in FIG. 7. The diffuser 118 is configured to alter an optical characteristic of light emitted by the device flash, e.g. diffuse light, alter/filter the color or intensity of the light, etc. The housing 102 includes a slider recess 114 that houses slider 112. Slider 112 is attached to diffuser 118 such that lateral motion of the slider 112 inside the recess 114 causes to the diffuser 118 to retract or extend in and out of the window 116 field-of-view.

The lateral motion of the slider 112 inside the recess 114 may also operate an on off switch for electronics mounted in the cavity 138. In certain embodiments, slider may be used as a latch to secure the cover 104 in a closed configuration with respect to housing 102.

FIG. 8 is a front perspective view of an alternative case 150 having a hinged cover 104 in an open configuration, and installed on a mobile device (e.g. cellular phone) in accordance with the present invention. Case 150 is similar to case 100, except that case 150 offers a built-in light 152 instead of diffuser 118. Light 152 may be switched on by the user to provide illumination of either the user, or objects in the vicinity of the user.

As shown in FIG. 8, cover 104 is extended in an open configuration to show recessed cargo area 106 of the housing 102, in addition to retaining space 125 of the cover 104. Cover 104 comprises a plurality of tabs 128 extending into retaining space 128. Tabs 128 allow for articles (e.g. bills, credit cards, or the like) held in retaining space 126 to be retained while the cover 104 is in an open configuration. The recessed cargo area 106 comprises a generally planar recessed surface 130 that runs parallel to the plane of the back of the handheld device.

Recessed surface 130 of cargo area 106 may comprise a reflective material to provide a mirrored surface or the like. The mirrored surface 130 may be use in conjunction with the light 152, or the device flash in case 100 of FIG. 7, to provide an illuminated vanity mirror. Mirrored surface 130 may be a mirror, laminate, coating, or other material providing a reflective quality.

It is appreciated that recessed surface 130 may also comprise other materials or textures, e.g. surface 130 may be a polymer having a highly tactile surface for gripping and retaining objects within cargo area 106. Top surface 144 of cover 104 also includes a slot 154 configured to allow for gripping the cover 104 to pull the cover 104 in the open configuration (e.g. with index finger).

To minimize the thickness of the case 100/150, it is also appreciated that the back surface 130 may be removed altogether, essentially leaving a window (not shown) to the back surface of the device. In this configuration, a backing (not shown) may be applied (e.g. adhesive backing or the like) to the back surface of the device to add additional protection to that surface. The adhesive backing may comprise a transparent, reflective, textured, or other type of surface according to the user's preference. In this configuration, either the back surface of the device or the backing act as the recessed cargo area surface when the case 100/150 is attached to the device.

Although cases 10, 100 and 150 shown in FIGS. 1-4 and 7-12 show a cover 14, 104 having a hinge 16, 100 at the bottom or lower edge of the case housing 12, 102, (with a horizontal hinge axis and cover 14, 104 opening in a downward rotation), it is appreciated that the hinge may also be positioned at other locations within the case. For example the hinge 16, 100 may be located at a side edge of the case housing 12, 102, with a vertical hinge axis and cover 14, 104 opening in a left or right lateral rotation (not shown).

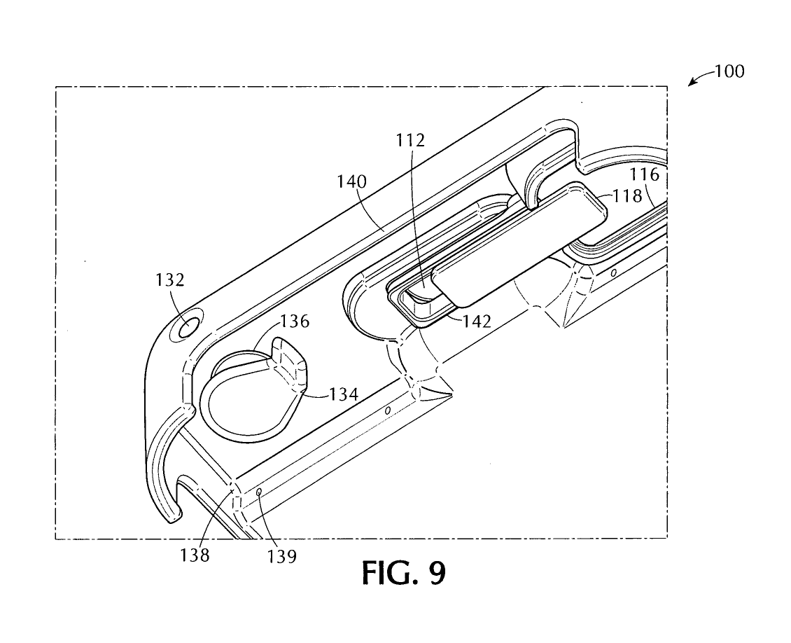

FIG. 9 shows a rear close-up perspective view of the case 100. Case housing 102 includes a component storage area 130 to provide placement of desired or interchangeable components. In the example shown in FIG. 9, a lanyard clip 134 is provided for retaining a lanyard (not shown). Lanyard clip 134 is retained in receiver 136 for releasable retention of the clip 134. It is appreciate the receiver 136 may be used to interchangeably house or mount other components, e.g. circuitry for other electronic components (e.g. light shown in FIG. 8). In other embodiments, various electronics, switches, mechanical devices, power sources, sensors, emitters, transmitters, communication devices or computing devices may be integrated into the casing and/or the cargo space 130 in a continuous mold or fitted to the casing and/or cargo space with receiver 136, or held in place with screws, threaded attachment, snaps, clasps, hasps and/or adhesives. Case housing 102 also comprises hole 132 for passing through a lanyard (not shown) or as an aperture for a sensor, emitter switch or botton, and upper opening 140 to provide access to various device components. FIG. 9 also illustrates bottom side of slider 112 and diffuser 118 shown retained in slot 142 in an extended configuration into camera window 116.

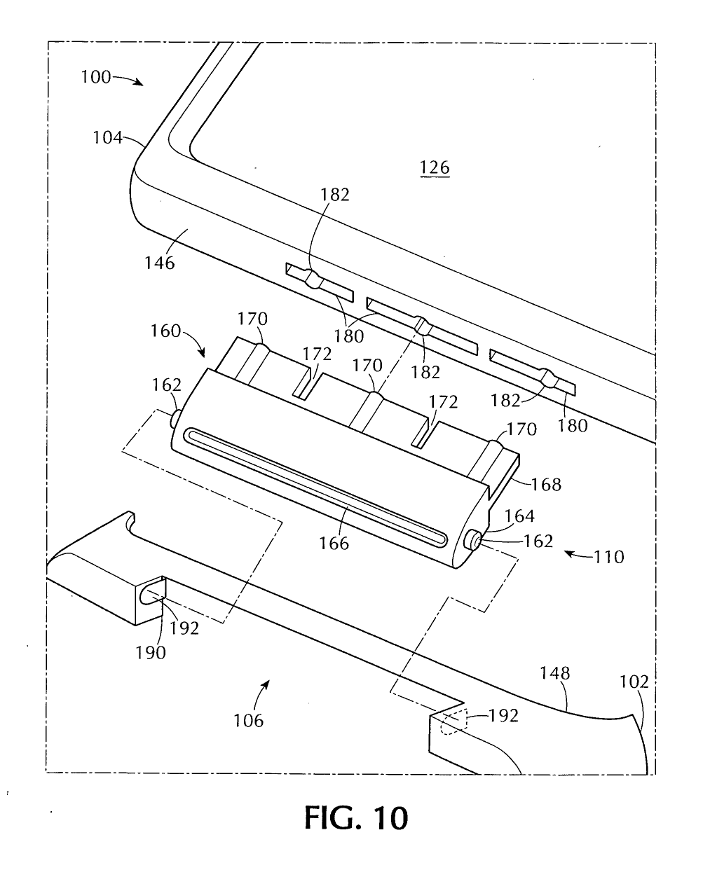

FIG. 10 shows an exploded perspective view of the hinge 110 and cover 104 of case 100/150. Hinge 110 includes a hinge insert 160 for rotatably coupling the case housing 102 to the modular interchangeable cover 104. Hinge insert 160 comprises an insert body 164 integrally coupled to a plurality of tabs 168. Insert body 164 also includes a pair of laterally positioned protrusions 162 that extend from the sides of the insert body 164. Protrusions 162 are concentrically aligned within the same axial centerline to act as a pin for engaging hinge receiving holes 192 at lower or hinge end 148 in the case housing 102. The receiving holes 192 are aligned to face each other on opposite ends of hinge opening 190, which is generally in communication with open area or cargo space 106. When engaged, the protrusions 162 are retained within receiving holes 192 so that the cover 104 does not translate with respect to the housing 102, but yet allows for rotation of the cover 104 from the closed or stowed orientation shown in FIG. 7 to the open orientation shown in FIG. 8.

Insert tabs 168 are configured to slideably mate with one or more receiving apertures 180 in the bottom or fixed end 146 of modular cover 104. Receiving apertures 180 extend into the cover 104 in a plane substantially parallel to outer surface 124 of the cover 104. Tabs 168 are sized to have a contact fit with receiving apertures 180. Such contact fit may be a friction fit or interference fit depending on the desired ease of detachment of the cover 104 with the insert 160. It is appreciated that the receiving tabs 168 may also or alternatively have a slight taper away from the tab body 164 so that they snugly engage the receiving apertures 180. Tabs 168 are shown with curvilinear raised sections 170 that fit into and mate with circular openings 182 of apertures 180. The shape of apertures 180 and corresponding features 172 and 170 on tabs 168 act to provide a locking interface to prevent lateral motion and rotation of the hinge insert 160 with respect to the cover 104. This configuration promotes only sliding motion in the direction of insertion, which allows for attaching and detaching the cover 104 to case housing 102. Apertures 180 act as key-holes to closely match the specified shape of the keys or tabs 168.

It is appreciated that tabs 168 and apertures 180 may have different, shapes, sizes, configurations, etc. and vary in number to affect different engagement characteristics as desired. Furthermore, it is appreciated that the hinge pin configuration may be reversed, i.e. the pin protrusions 162 may reside on opposite ends of hinge opening 190 of case 102 (not shown), with corresponding apertures (not shown) at locations where pins 162 currently reside on the insert body 164.

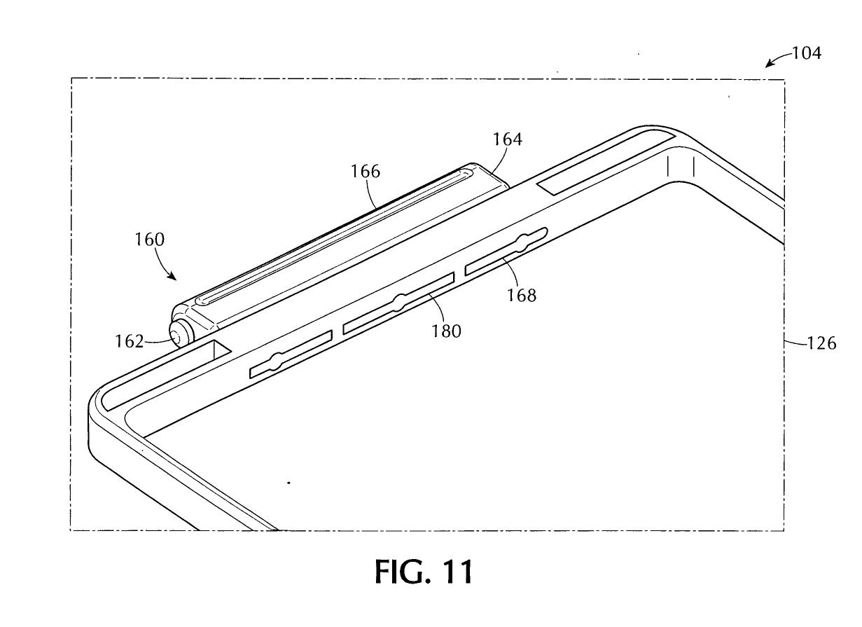

As shown in FIGS. 10 and 11, insert body 164 also comprises one or more raised ridges 166 that are configured to engage the edge of end 148 of housing 102 during certain stages of the rotation between the stowed state of FIG. 7 and open state of FIG. 8, to thereby impede further rotation of cover 104 (e.g. to temporary lock rotation of the cover 104 at a certain range of rotation for access to the cover 104 or articles contained therein).

As shown in the perspective view of FIG. 11, the hinge insert 160 is fully installed into the cover 104, with tabs 168 extending generally along the length of receiving apertures 180. It is appreciated that the length of tabs 168 may be sized to extend into the receiving space 126 of cover 104 (not shown) to snap or engage with the wall defining its boundary (the distal ends of tabs 168 may have a hook-like protrusion (not shown) to lock into receiving space 126. Other locking means are also contemplated, e.g. a pin, grommet, rivet snap, or like fastener may be installed through end 104 of cover and tabs 168 (orthogonal to tab 168 sliding plane) to lock the tab in place within aperture 180.

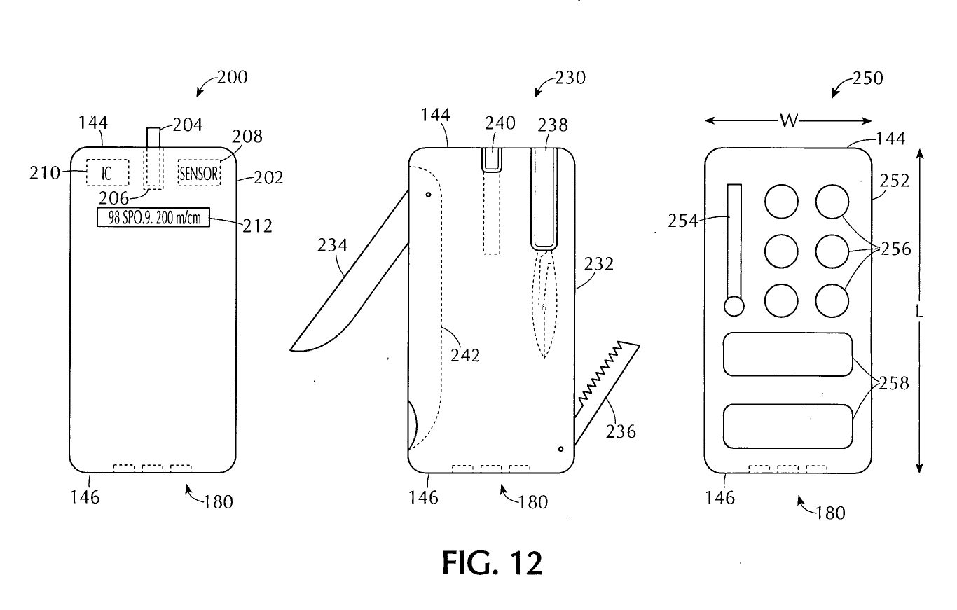

In a preferred embodiment, the hinge 110 and hinge insert is configured to provide a standardized interface for releasably attaching varying interchangeable covers 104 (e.g. covers 200, 230 and 250 shown in FIG. 12), each having unique features that may be desired by the user at a particular time. Thus, a user may remove the cover 104 by simply slideably detaching it from the hinge insert 160, and then inserting another cover (e.g. covers 200, 230 and 250, or the like) having a set of matching receiving apertures on to tabs 168 of the hinge 110. This allows for the user to conveniently switch to a particular module of choice, without having to remove the case 100/150 from the mobile device.

This standardized hinge interface also allows the various covers 104 to be readily attached to other case housings 102 that may be attached to different devices (e.g. another user's phone, or a different device of the same user). Generally cellular phones are upgraded or become obsolete within a short period of time (1-2 years), and most phone upgrades change the shape of the device and/or location of controls, functions or inputs to the device. The result is that the case housing 102 no longer fits or is functional with the new device. Thus, if the user has spent significant expense with modular covers that perform various functions that are independent of the phone, but are still of value to the user, it would still be desirable to use the cover 104 on the new device. With the standardized interchangeable system of the present invention, a new housing 102 (fitting the form of the new device) may be installed having the hinge configuration 110 of FIGS. 10 and 11, which allows the old covers/modules 104 to be readily attached to the existing hinge insert 160.

It is appreciated that the hinge insert 160 may simply be integral (not shown) with the cover 104 (i.e. the hinge body 164 and protrusions 102 simply being fabricated as the same mold as the cover 104). In this configuration, the cover 104 would be interchanged by pulling the cover protrusions 162 out from the hinge apertures 192. However, the hinge insert 160 provides a convenient means of detaching/attaching various modules/covers 104, without the modules having the hinge protrusion for attachment, i.e. the cover 104 remains a clean, rectangular shape that is both aesthetically pleasing and more advantageous for storing or carrying separately.

FIG. 12 is a plan view of a set of different interchangeable covers 200, 230, and 250 that are configured to couple with the standardized cargo interface 106 of the case housing 102 and hinge insert tabs 168 shown in FIGS. 10 and 11. One or more of covers 104, 200, 230 and 250 may be used individually, or as a system, in conjunction with housing 102,

Interchangeable covers 200, 230, and 250 preferably comprise a standardized shape that corresponds with the cargo depression 106 of the housing 102. Generally, each cover will have a length L and width W that matches, or is slightly smaller than the length and width of the cargo area 106. Each cover 200, 230, and 250 will also have a thickness that matches the depth of the cargo area 106, although is contemplated that that thickness may be smaller than or larger than the cargo space 106 depth.

Each of the interchangeable covers 200, 230, and 250 also have a bottom or hinge end 146 having receiving apertures 180 corresponding to the tabs 168 of the hinge insert 160. Free or top end 144 of each the interchangeable covers 200, 230, and 250 may also comprise a slot 154 for gripping the cover 104, as shown in FIG. 8.

Interchangeable cover 200 is shown as an integrated medical sensor 208 configured to measure and analyze various physiological characteristics of a user. Interchangeable cover 200 comprises a receiving slot 206 for lancets/test strips 204 that may be read by sensor 208 for various measurements, such as blood glucose monitoring. Integrated circuitry 210 provides processing, memory, and programming configured to receive and/or analyze the data received from sensor 208. Integrated circuitry 210 may also comprise a wireless transmitter/receiver (e.g. wifi, Bluetooth, etc.) for sending data to the mobile device, or other device. Results from the measurements of sensor 208 may be shown on display 212 that is integrated within casing 202. The cover 200, and/or sensor 208, may also comprise other sensor capabilities for measuring other characteristics, e.g. oximeter and pulse meter, temperature sensor, saliva, urine, or blood analysis, etc. It is also appreciated that the cover 200 may interface directly with a port (not shown) of the mobile device in alternative to, or in conjunction with, wireless communication. Cover 200 may have an independent power source (e.g. battery not shown) to provide power to the sensor 208 and circuitry 210, or have a port (not shown) for charging/recharging the battery.

Interchangeable cover 230 is a modular cover having a multi-tool comprising various tools that may be extended or detached from corresponding cavities 242 in the cover casing 232. Exemplary tools may include knife 204, file 240, scissors 238, saw 236, or other tools known in the art. Access to the tools may be provided by opening cover 230 to an open configuration, or by separating cover 230 from hinge insert 160.

Interchangeable cover 250 includes a cosmetic case 252 for housing makeup or facial products 256, 258 and applicators 254. Along with the reflective surface 130 and light from either the built-in illumination source 152 (FIG. 8) or the device's illumination source, the cover 250 effectively turns the mobile device into a lighted compact.

It is appreciated that any number of possible features including, but not limited to tools, keys, lanyards, kickstands, writing instruments, personal identification holders, personal safety items, billfolds, cosmetics, mirrors, lenses, medical instruments, writing instruments, musical instruments, measuring devices, GPS transceivers, and tracking beacons may be employed in the form of electronics, switches, mechanical devices, power sources, sensors, emitters, transmitters or computing devices, and thus may be incorporated into the interchangeable covers 104, 200, 230, and 250. Furthermore, such features may be used interchangeably within such covers as applicable.

The various housings and covers are preferably manufactured by the processes of thermoplastic/thermosetting plastic and/or metal injection molding. However, it is appreciated that other manufacturing processes may also be employed.

From the above description, it will be appreciated that the present invention can be embodied in various ways, which include but are not limited to the following:

1. A case for handheld electronic device, comprising: a housing; the housing configured to couple to and cover at least a portion of one or more surfaces of the handheld electronic device; a detachable cover; the detachable cover having a free end and a fixed end opposite the free end, the fixed end forming a hinge with the housing; wherein the fixed end of the cover is configured to be detachably released from the housing at said hinge; the housing having a recessed cargo area configured to retain one or more articles within the case; wherein the cover is configured to rotate at the hinge from a stowed configuration to an open configuration with respect to the housing; wherein in the stowed configuration the free end of the cover is positioned adjacent the housing to enclose the cargo area; and wherein in the open configuration the free end of the cover is rotated away from the housing to expose the cargo area.

2. A case as recited in embodiment 1, wherein in the closed configuration the cover is at least partially disposed within the cargo area.

3. A case as recited in embodiment 1: wherein the hinge comprises a hinge insert; the hinge insert comprising an insert body and one or more tabs; the hinge body configured to be rotatably attached to the housing; the one or more tabs configured to slideably engage the fixed end of the cover; and wherein the cover is configured to detach from the housing by slideably disengaging the cover from the one or more tabs.

4. A case as recited in embodiment 3: wherein the cargo area comprises a generally planar recessed surface; wherein the cover comprises at least one planar surface configured to be substantially parallel to the recessed surface when the cover is oriented in the stowed configuration; wherein the cover comprises one or more receiving apertures at the fixed end of the cover; wherein the one or more receiving apertures extend into the cover in a plane substantially parallel to the planar surface of the cover; and wherein the one or more receiving apertures are sized to slideably receive the one or more tabs of the hinge insert to releasably engage the cover with the hinge insert.

5. A case as recited in embodiment 3: wherein the hinge insert and housing comprise: a pair of concentrically oriented hinge protrusions; and a pair of hinge openings configured to receive said hinge protrusions.

6. A case as recited in embodiment 1: wherein the housing comprises a window; the window allowing line of sight for a camera and illumination source of the handheld electronic device; the housing further comprising a diffuser retractably coupled to the housing; and wherein the diffuser is configured to retractably extend into the line of sight of the illumination source to alter an optical characteristic of light emitted by the illumination source.

7. A case as recited in embodiment 3: wherein the cargo area of the housing comprises a generally planar recessed surface; and wherein said the planar recessed surface comprises a reflective surface.

8. A case as recited in embodiment 1: wherein the cover comprises an outer planar surface and an inner recessed surface opposite the outer planar surface; the inner recessed surface configured to retain one or more articles; wherein the cargo area of the housing comprises a generally planar recessed surface; wherein the outer planar surface is configured to be substantially parallel to the recessed surface of the cargo area and substantially flush with the housing recess when the cover is oriented in the stowed configuration.

9. A case as recited in embodiment 1: wherein the cover comprises a sensor; the sensor configured to sense one or more physiological characteristics of a user.

10. A system for encasing a handheld electronic device, comprising: a housing; the housing configured to couple to and cover at least a portion of one or more surfaces of the handheld electronic device; the housing having a recessed cargo area; a first interchangeable cover; a second interchangeable cover; the first and second interchangeable covers configured to be interchangeably attached to the housing; the first and second interchangeable covers each having a free end and a fixed end opposite the free end, the fixed end releasably forming a hinge with the housing; wherein the fixed end is configured to be detachably released from the housing at said hinge; wherein the first interchangeable cover or second interchangeable cover, when attached to the housing, are configured to rotate at the hinge from a stowed configuration to an open configuration with respect to the housing; wherein in the stowed configuration the free end of the cover is positioned adjacent the housing to enclose at least a portion of the cargo area; and wherein the first interchangeable cover or second interchangeable are sized and shaped to substantially match the size and shape of the recessed cargo area; and wherein in the open configuration the free end of the cover is rotated away from the housing to expose the cargo area.

11. A system as recited in embodiment 10, wherein the cargo area is configured to retain one or more articles within the case.

12. A system as recited in embodiment 10: wherein the hinge comprises a hinge insert; the hinge insert comprising an insert body and one or more tabs; the hinge body configured to be rotatably attached to the housing; the one or more tabs configured to slideably engage the fixed end of the first and second interchangeable covers; and wherein the first and second interchangeable covers are configured to detach from the housing by slideably disengaging the first or second interchangeable cover from the one or more tabs.

13. A system as recited in embodiment 12: wherein the cargo area comprises a generally planar recessed surface; wherein the first and second interchangeable covers comprise at least one planar surface configured to be substantially parallel to the recessed surface when the first or second interchangeable cover is oriented in the stowed configuration; wherein the first and second interchangeable covers comprise one or more receiving apertures at the fixed end of the cover, the one or more receiving apertures of the first interchangeable cover being substantially identical to the one or more receiving apertures of the second interchangeable cover; wherein the one or more receiving apertures extend into the first and second interchangeable covers in a plane substantially parallel to the planar surface of the first and second interchangeable covers; and wherein the one or more receiving apertures are sized to slideably receive the one or more tabs of the hinge insert to releasably engage the first or second interchangeable covers with the hinge insert.

14. A system as recited in embodiment 12: wherein the hinge insert and housing comprise: a pair of concentrically oriented hinge protrusions; and a pair of hinge openings configured to receive said hinge protrusions.

15. A system as recited in embodiment 12: wherein the cargo area of the housing comprises a generally planar recessed surface; and wherein said the planar recessed surface comprises a reflective surface.

16. A system as recited in embodiment 10: wherein the first and second interchangeable covers comprise an outer planar surface; and wherein the outer planar surface is configured to be substantially parallel to the recessed surface of the cargo area and substantially flush with the housing recess when the first or second interchangeable covers is oriented in the stowed configuration.

17. A case for handheld electronic device, comprising: a housing; the housing configured to couple to and cover at least a portion of one or more surfaces of the handheld electronic device; the housing having a recessed cargo area; a detachable cover; the detachable cover having a free end and a fixed end opposite the free end, the fixed end forming a hinge with the housing; wherein the hinge comprises a hinge insert; the hinge insert comprising an insert body and one or more tabs; the hinge body configured to be rotatably attached to the housing; the one or more tabs configured to slideably engage the fixed end of the cover; and wherein the cover is configured to detach from the housing by slideably disengaging the fixed end of the cover from the one or more tabs. 18. A case as recited in embodiment 17: wherein the cover is configured to rotate at the hinge from a stowed configuration to an open configuration with respect to the housing; wherein in the stowed configuration the free end of the cover is positioned adjacent the housing to enclose the cargo area; and wherein in the open configuration the free end of the cover is rotated away from the housing to expose the cargo area.

19. A case as recited in embodiment 18: wherein the cargo area comprises a generally planar recessed surface; wherein the cover comprises at least one planar surface configured to be substantially parallel to the recessed surface when the cover is oriented in the stowed configuration; wherein the cover comprises one or more receiving apertures at the fixed end of the cover; wherein the one or more receiving apertures extend into the cover in a plane substantially parallel to the planar surface of the cover; and wherein the one or more receiving apertures are sized to slideably receive the one or more tabs of the hinge insert to releasably engage the cover with the hinge insert.

20. A case as recited in embodiment 18: wherein the cover comprises an outer planar surface and an inner recessed surface opposite the outer planar surface; the inner recessed surface configured to retain one or more articles; wherein the cargo area of the housing comprises a generally planar recessed surface; wherein the outer planar surface is configured to be substantially parallel to the recessed surface of the cargo area and substantially flush with the housing recess when the cover is oriented in the stowed configuration.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. A case for handheld electronic device, comprising:
a housing;
the housing configured to couple to and cover at least a portion of one or more surfaces of the handheld electronic device;
a detachable cover;
the detachable cover having a free end and a fixed end opposite the free end, the fixed end forming a hinge with the housing;
wherein the fixed end of the cover is configured to be detachably released from the housing at said hinge;
the housing having a recessed cargo area configured to retain one or more articles within the case;
wherein the cover is configured to rotate at the hinge from a stowed configuration to an open configuration with respect to the housing;
wherein in the stowed configuration the free end of the cover is positioned adjacent the housing to enclose the cargo area; and
wherein in the open configuration the free end of the cover is rotated away from the housing to expose the cargo area.

2. A case as recited in claim 1, wherein in the closed configuration the cover is at least partially disposed within the cargo area.

3. A case as recited in claim 1:
wherein the hinge comprises a hinge insert;
the hinge insert comprising an insert body and one or more tabs;
the hinge body configured to be rotatably attached to the housing;
the one or more tabs configured to slideably engage the fixed end of the cover; and
wherein the cover is configured to detach from the housing by slideably disengaging the cover from the one or more tabs.

4. A case as recited in claim 3:
wherein the cargo area comprises a generally planar recessed surface;
wherein the cover comprises at least one planar surface configured to be substantially parallel to the recessed surface when the cover is oriented in the stowed configuration;
wherein the cover comprises one or more receiving apertures at the fixed end of the cover;
wherein the one or more receiving apertures extend into the cover in a plane substantially parallel to the planar surface of the cover; and
wherein the one or more receiving apertures are sized to slideably receive the one or more tabs of the hinge insert to releasably engage the cover with the hinge insert.

5. A case as recited in claim 3:
wherein the hinge insert and housing comprise:
a pair of concentrically oriented hinge protrusions; and
a pair of hinge openings configured to receive said hinge protrusions.

6. A case as recited in claim 1:
wherein the housing comprises a window;
the window allowing line of sight for a camera and illumination source of the handheld electronic device;
the housing further comprising a diffuser retractably coupled to the housing; and
wherein the diffuser is configured to retractably extend into the line of sight of the illumination source to alter an optical characteristic of light emitted by the illumination source.

7. A case as recited in claim 3:
wherein the cargo area of the housing comprises a generally planar recessed surface; and
wherein said the planar recessed surface comprises a reflective surface.

8. A case as recited in claim 1:
wherein the cover comprises an outer planar surface and an inner recessed surface opposite the outer planar surface;
the inner recessed surface configured to retain one or more articles;
wherein the cargo area of the housing comprises a generally planar recessed surface;
wherein the outer planar surface is configured to be substantially parallel to the recessed surface of the cargo area and substantially flush with the housing recess when the cover is oriented in the stowed configuration.

9. A case as recited in claim 1:
wherein the cover comprises a sensor;
the sensor configured to sense one or more physiological characteristics of a user.

10. A system for encasing a handheld electronic device, comprising:
a housing;
the housing configured to couple to and cover at least a portion of one or more surfaces of the handheld electronic device;
the housing having a recessed cargo area;
a first interchangeable cover;
a second interchangeable cover;
the first and second interchangeable covers configured to be interchangeably attached to the housing;
the first and second interchangeable covers each having a free end and a fixed end opposite the free end, the fixed end releasably forming a hinge with the housing;
wherein the fixed end is configured to be detachably released from the housing at said hinge;
wherein the first interchangeable cover or second interchangeable cover, when attached to the housing, are configured to rotate at the hinge from a stowed configuration to an open configuration with respect to the housing;
wherein in the stowed configuration the free end of the cover is positioned adjacent the housing to enclose at least a portion of the cargo area; and
wherein the first interchangeable cover or second interchangeable are sized and shaped to substantially match the size and shape of the recessed cargo area; and
wherein in the open configuration the free end of the cover is rotated away from the housing to expose the cargo area.

11. A system as recited in claim 10, wherein the cargo area is configured to retain one or more articles within the case.

12. A system as recited in claim 10:
wherein the hinge comprises a hinge insert;
the hinge insert comprising an insert body and one or more tabs;
the hinge body configured to be rotatably attached to the housing;
the one or more tabs configured to slideably engage the fixed end of the first and second interchangeable covers; and
wherein the first and second interchangeable covers are configured to detach from the housing by slideably disengaging the first or second interchangeable cover from the one or more tabs.

13. A system as recited in claim 12:
wherein the cargo area comprises a generally planar recessed surface;
wherein the first and second interchangeable covers comprise at least one planar surface configured to be substantially parallel to the recessed surface when the first or second interchangeable cover is oriented in the stowed configuration;
wherein the first and second interchangeable covers comprise one or more receiving apertures at the fixed end of the cover, the one or more receiving apertures of the first interchangeable cover being substantially identical to the one or more receiving apertures of the second interchangeable cover;
wherein the one or more receiving apertures extend into the first and second interchangeable covers in a plane substantially parallel to the planar surface of the first and second interchangeable covers; and
wherein the one or more receiving apertures are sized to slideably receive the one or more tabs of the hinge insert to releasably engage the first or second interchangeable covers with the hinge insert.

14. A system as recited in claim 12:
wherein the hinge insert and housing comprise:
a pair of concentrically oriented hinge protrusions; and
a pair of hinge openings configured to receive said hinge protrusions.

15. A system as recited in claim 12:
wherein the cargo area of the housing comprises a generally planar recessed surface; and
wherein said the planar recessed surface comprises a reflective surface.

16. A system as recited in claim 10:
wherein the first and second interchangeable covers comprise an outer planar surface; and
wherein the outer planar surface is configured to be substantially parallel to the recessed surface of the cargo area and substantially flush with the housing recess when the first or second interchangeable covers is oriented in the stowed configuration.

17. A case for handheld electronic device, comprising:
a housing;
the housing configured to couple to and cover at least a portion of one or more surfaces of the handheld electronic device;
the housing having a recessed cargo area;
a detachable cover;
the detachable cover having a free end and a fixed end opposite the free end, the fixed end forming a hinge with the housing;
wherein the hinge comprises a hinge insert;
the hinge insert comprising an insert body and one or more tabs;
the hinge body configured to be rotatably attached to the housing;
the one or more tabs configured to slideably engage the fixed end of the cover; and
wherein the cover is configured to detach from the housing by slideably disengaging the fixed end of the cover from the one or more tabs

18. A case as recited in claim 17:
wherein the cover is configured to rotate at the hinge from a stowed configuration to an open configuration with respect to the housing;
wherein in the stowed configuration the free end of the cover is positioned adjacent the housing to enclose the cargo area; and
wherein in the open configuration the free end of the cover is rotated away from the housing to expose the cargo area.

19. A case as recited in claim 18:
wherein the cargo area comprises a generally planar recessed surface;
wherein the cover comprises at least one planar surface configured to be substantially parallel to the recessed surface when the cover is oriented in the stowed configuration;
wherein the cover comprises one or more receiving apertures at the fixed end of the cover;
wherein the one or more receiving apertures extend into the cover in a plane substantially parallel to the planar surface of the cover; and
wherein the one or more receiving apertures are sized to slideably receive the one or more tabs of the hinge insert to releasably engage the cover with the hinge insert.

20. A case as recited in claim 18:
wherein the cover comprises an outer planar surface and an inner recessed surface opposite the outer planar surface;
the inner recessed surface configured to retain one or more articles;
wherein the cargo area of the housing comprises a generally planar recessed surface;
wherein the outer planar surface is configured to be substantially parallel to the recessed surface of the cargo area and substantially flush with the housing recess when the cover is oriented in the stowed configuration.
